(19) United States
(12) Patent Application Publication
(10) Pub. No.: US 2008/0153246 A1
(43) Pub. Date: Jun. 26, 2008

(54) TRIDIMENSIONAL INTEGRATED RESISTOR

(75) Inventors: Benjamin Renard, Saint Etienne de Chigny (FR); Sylvain Nizou, Noizay (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 11/846,635

(22) Filed: Aug. 29, 2007

(30) Foreign Application Priority Data
Aug. 31, 2006 (FR) FR 06/53542

(51) Int. Cl. H01L 21/22

(52) U.S. Cl. 438/382; 257/E21.004

(57) ABSTRACT

A resistor formed in a semiconductor substrate of a first conductivity type comprising parallel trenches, the resistor being formed of a layer of the second conductivity type extending on two opposite walls and the bottom of at least one trench.

### BACKGROUND OF THE INVENTION

1. Field of the Invention

The present invention relates to the forming of resistors in semiconductor components.

2. Discussion of the Related Art

Conventionally, resistors are formed in discrete or integrated semiconductor circuits in the form of doped areas specifically formed in the surface of a semiconductor wafer, or in the form of layers deposited on the surface of a semiconductor wafer, possibly with an interposed insulating layer.

A disadvantage of such resistors is that they are arranged in a plane, and thus take up a relatively large surface area. Thus, various attempts have been made to form tridimensional resistors, that is, in which at least a portion of the current path extends perpendicularly to the main surface of a semiconductor substrate. However, such resistors all exhibit various disadvantages.

### SUMMARY OF THE INVENTION

An aspect of the present invention also aims at a particularly simple and accurate method for manufacturing a tridimensional resistor, having at least one of the following advantages:

reduced occupation of surface area,

simplicity of forming and compatibility with conventional semiconductor component manufacturing steps,

good accuracy and good predictability of the resistance value.

An embodiment of the present invention provides a method for forming a resistor comprising the steps of forming trenches in a semiconductor substrate; and doping by implantation two opposite walls and the bottom of each trench.

According to an embodiment of the present invention, the trenches have opposite vertical walls and the implantation of the opposite walls results from oblique implantations.

According to an embodiment of the present invention, the trenches have V-shaped opposite oblique walls and the implantation of the opposite walls results from a vertical implantation.

According to an embodiment of the present invention, before the implantation step, a thin oxide layer is formed on the trench walls.

According to an embodiment of the present invention, said oxide layer is eliminated after the implantation.

According to an embodiment of the present invention, after forming of the implantations, the trenches are filled with an insulating material.

The foregoing and other objects, features, and advantages of the present invention will be discussed in detail in the following non-limiting description of specific embodiments in connection with the accompanying drawings.

### BRIEF DESCRIPTION OF THE DRAWINGS

FIGS. 1A and 1B respectively show a perspective cross-section view and a top view of an embodiment of a resistor according to the present invention, the cross-section view of FIG. 1A being performed along plane A-A of FIG. 1B; and

FIGS. 2A to 2K are simplified cross-section views illustrating successive steps of an example of a method for manufacturing a resistor according to an embodiment of the present invention.

### DETAILED DESCRIPTION

For clarity, the same elements have been designated with the same reference numerals in the different drawings and, further, as usual in the representation of integrated circuits, the various drawings are not to scale.

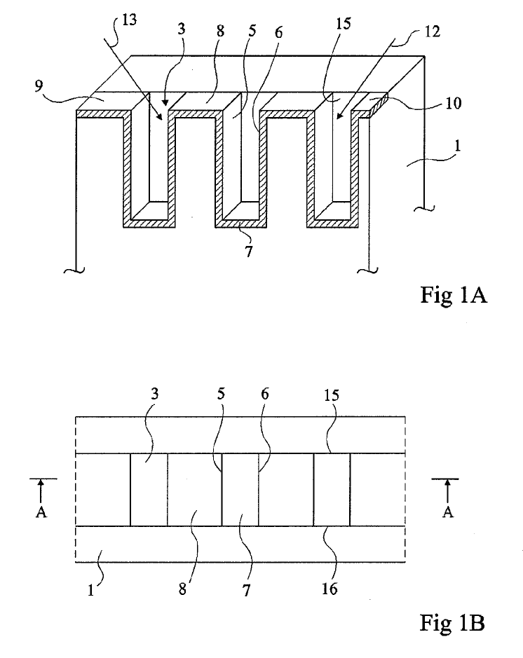

As illustrated in FIGS. 1A and 1B, a resistor according to an embodiment of the present invention is formed in a portion of a semiconductor substrate 1 of a first conductivity type, for example, a lightly-doped P-type single-crystal silicon substrate. Parallel trenches 3 are formed in this substrate. The two opposite walls 5 and 6 and bottom 7 of each trench are heavily doped according to the conductivity type opposite to that of the semiconductor substrate (N⁺ doping in this example). The resistor is formed by the vertical path along wall 5, the horizontal path along bottom 7, and the vertical path along wall 6 in the heavily-doped layer. A connection is ensured at the surface by conductive elements 8 between the tops of the conductive portions of two adjacent trenches. In the example of FIG. 1A, conductive element 8 connecting two walls back-to-back of two adjacent trenches is formed of a doped layer similar to that coating the walls and the bottom of the trenches. Conductive element 8 then is an element of the resistor. However, any other connection means may be provided.

A resistor may be formed from a trench or from several trenches in series, as shown. End portions 9 and 10 form elements of connection to connection terminals of the resistor.

Such a resistor will have a behavior similar to that of a diffused resistor formed at the surface of a semiconductor substrate. Indeed, it corresponds to a heavily-doped layer of low thickness extending on a semiconductor surface of opposite conductivity type, even though, in the described embodiment of the present invention, this surface is now horizontal, now vertical. Its resistance value, its length, and its other characteristics can thus be defined with accuracy and the value of its resistance is then well predictable from the moment that trenches of known depth and extension have been formed.

Further, this resistor only involves layers of doped materials of different conductivity types, that is, the basic materials of semiconductor component manufacturing, and does not require introduction of specific materials which might be incompatible with the forming of other semiconductor components in a same substrate.

It should be understood that the diffusions on opposite walls 5 and 6 may be obtained from two implantations inclined in the direction of arrows 12 and 13. The angle of such inclined implantations will be selected in relation with the depth of the trenches so that the entire height of the concerned walls (5 or 6), as well as bottom 7 of the trenches, are bombarded by dopant elements. However, it should be ascertained that the implantation angle has a low dispersion so that the lateral walls which are not concerned, that is, walls 15 and opposite wall 16, are not doped. Various measures can be taken to avoid such dopings of the lateral walls and examples thereof will be given hereafter.

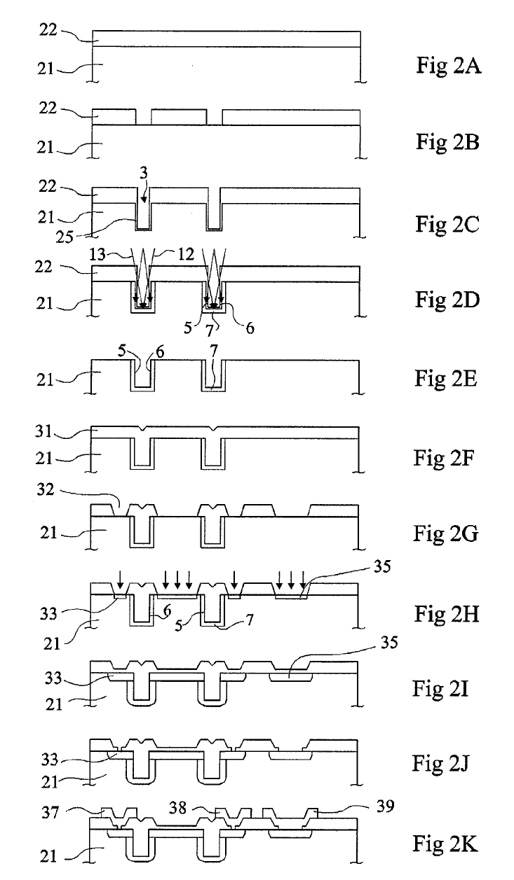

FIGS. 2A to 2K illustrate, as an example only, successive steps of a possible method for manufacturing a structure according to an embodiment of the present invention.

At the step illustrated in FIG. 2A, a silicon substrate 21 is covered with a silicon oxide layer 22 or another material selectively etchable with respect to silicon and that can be used as an implantation mask.

At the step illustrated in FIG. 2B, openings have been formed in silicon oxide layer 22, at the locations where trenches are desired to be formed.

At the step illustrated in FIG. 2C, trenches 3 have been formed in silicon layer 21 and the walls of these trenches have been coated with a thin oxide layer 25, obtained for example by thermal oxidation.

At the step illustrated in FIG. 2D, oblique implantations following orientations 12 and 13 are performed to implant an N-type dopant, if the silicon substrate is P-type doped, on opposite walls 5 and 6 of the trenches as well as on bottom 7 thereof.

The advantage of providing thin oxide layer 25 formed at the step illustrated in FIG. 2C is to protect opposite lateral walls 15 and 16 (see FIGS. 1A and 1B) in which no dopant ions are desired to be implanted. Given that, inevitably, some parasitic dopant ions are directed towards opposite lateral walls 15 and 16, possible parasitic dopant particles, which necessarily have a lower power, will be absorbed by oxide layer 25 and will not penetrate into the silicon of the opposite lateral walls. However, the dopants implanted along directions 12 and 13 will cross layer 25 and penetrate into the silicon.

At the step illustrated in FIG. 2E, oxide layer 25 has been eliminated to avoid that the dopants which may be contained therein dope the lateral walls after the diffusion steps. The oxide layer or another hard mask 22 has also been removed.

At the step illustrated in FIG. 2F, the trenches are filled with a filling material. Indeed, in a semiconductor component, it is generally preferred to avoid that open trenches remain. And this, all the more as at other locations of the same wafer, other components will be manufactured and as the products used for these other components would risk penetrating into the trenches and disturbing their surfaces. The filling material, for example, is an insulator, for example, silicon oxide deposited by low-pressure vapor deposition.

At the step illustrated in FIG. 2G, insulator layer 31 is opened at locations 32 where active areas are desired to be defined. These active areas will especially contain elements of connection between resistive elements (between trenches) or contacting elements. Such active areas may also correspond to areas in which other components are formed.

At the step illustrated in FIG. 2H, an implantation is performed in the areas defined by some at least of openings 32 to form therein regions 33, for example, heavily N-type doped. In the shown example, an N region 35 which does not belong to the resistor or to its contacts has also been provided to the right of the drawing.

At the step illustrated in FIG. 2I, a slight oxidation or a diffusion anneal are preferably performed.

At the step illustrated in FIG. 2J, windows are opened towards the upper surface of diffused regions 33 corresponding to the resistor and towards the upper surface of region 35 corresponding to, for example, a diode.

At the step illustrated in FIG. 2K, a metal layer 37 is deposited and etched as appropriate to obtain in the shown fashion three areas, areas 37 and 38 of contact with the two ends of the resistor and an area 39 for contacting layer 35 of the diode formed between layer 35 and substrate 21.

The various steps illustrated in FIGS. 2A to 2K show but an exemplary embodiment of a resistor according to the present invention. This example illustrates that the resistor integration is incompatible with the forming of other conventional components in a same silicon wafer without requiring more than one additional mask (the trench definition mask), although this mask may be provided for the forming of other components.

It will be within the abilities of those skilled in the art to select the dimensions of the trenches and their depths as well as their spacings according to the available technology and to the result that they want to obtain. Trenches of a 0.8-μm opening, or a 2-μm step, and having a 23-μm depth, may, for example, be provided, that is, with a depth-to-width ratio on the order of 28. Then, the angle of incidence of the oblique implantations will have to be on the order of 1°. Generally, it will be selected for the trenches to have a depth-to-width ratio greater than 10, for example on the order of 30.

The present invention is likely to have many variations. For example, the trench walls have always been mentioned as being vertical. The walls on which the resistor extends may also be slightly inclined, for example, V-shaped. In this case, the implantation may be vertical. It has further been indicated that the layer forming the resistor was heavily doped. It should be noted by those skilled in the art that the selection of the doping level and of the implanted doses is one of the adjustment parameters of the resistance value.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for forming a resistor comprising the steps of:
forming trenches in a semiconductor substrate; and
doping by implantation two opposite walls and the bottom of each trench.

2. The method of claim 1, wherein the trenches have opposite vertical walls and the implantation of the opposite walls results from oblique implantations.

3. The method of claim 1, wherein the trenches have V-shaped opposite oblique walls and the implantation of the opposite walls results from a vertical implantation.

4. The method of claim 1, wherein, before the implantation step, a thin oxide layer is formed on the trench walls.

5. The method of claim 4, wherein said oxide layer is eliminated after the implantation.

6. The method of claim 1, wherein, after forming of the implantations, the trenches are filled with an insulating material.
